(19) United States
(12) Patent Application Publication
(10) Pub. No.: US 2020/0119645 A1
(43) Pub. Date: Apr. 16, 2020

(54) Apparatus for Inductive Current Amplification

(71) Applicant: Starv Power, LLC, Lexington, KY (US)

(72) Inventors: William Hammond, Lexington, KY (US); Kelly Hammond, Lexington, KY (US)

(73) Assignee: Starv Power, LLC, Lexington, KY (US)

(21) Appl. No.: 16/599,865

(22) Filed: Oct. 11, 2019

Related U.S. Application Data
(60) Provisional application No. 62/744,847, filed on Oct. 12, 2018.

(51) Int. Cl. H02M 3/158; H03K 4/72; H03K 6/02

(52) U.S. Cl. CPC H02M 3/158; H03K 6/02; H03K 4/72

(57) ABSTRACT

A device for the amplification of inductive current is disclosed. The device consists of a poly capacitor to smooth the electric flow of a circuit, a dielectric capacitor that interacts with an inductive coil, and a third trace, or conductive pathway to capture extraneous heat, distortion and electromotive flux present in the circuit. The dielectric capacitor is sized and configured to alter the normal cycles of the inductive coil to boost the magnetic flux in the coil. The third trace picks up this boosted flux to amplify the current of the inductor.

### CROSS REFERENCE TO RELATED APPLICATIONS

This application claims priority to U.S. provisional application Ser. No. 62/744,847, filed on Oct. 12, 2018, and incorporated fully herein by reference.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC

Not Applicable

### BACKGROUND OF THE INVENTION

### Field of the Invention

The present invention relates to an apparatus for amplifying the current across an inductive coil.

### SUMMARY OF THE INVENTION

The disclosed Inductive Power Amplification (IPA) system consists of a unique electromagnetic circuit that produces constant Inductive Power by amplifying the current across an inductor. The IPA circuit across the inductor yields amplified current that is stable (60 HZ) and produced at any desired wattage. The circuit is set apart by its output power which is characterized as paired Inductive Power rather than conventional AC or DC power.

The IPA circuit is unique in its design configuration, assemblage, and use of electronic components. Component parts in the IPA circuit are utilized unconventionally. A poly-capacitor (hybrid capacitor made of polystyrene and tantalum) is used to smooth current fluctuation like a smoothing capacitor would do in a conventional circuit, and the IPA circuit also uses a “choke” not to block AC or DC, but as an inductor interrupting device to prohibit completion of the natural power conversion cycles. In one embodiment the poly-capacitor charges and discharges in sequence—or out of sequence—with the cycle of the windings on the inductor which prevents the completion of the natural conversion cycle, and this boosts the output of the inductor. Next, the IPA circuit incorporates a “third trace” or conductive pathway circuit to capture and direct field flux power continuously throughout the circuit. In employing these design/use deviations from conventional electric circuits, IPA technology produces amplified Power greater than the input power supplied. This amplified power offers greater efficiency & flexibility in electrical application circuits.

The “third trace” or conductive pathway to capture and direct noise, distortion, heat, and stray flux power continuously throughout the circuit. Standard electrical circuits constantly lose a portion of their energy through heat loss, distortion, and through the electromagnetic flux present in flowing electric current. The third trace, which can be incorporated into the primary circuit, or added as separate circuitry, picks up this ambient energy and redirects it back into the circuitry. By calculating the maximum load resistance given voltage and current through the IPA technology we demonstratively show voltage (V) across a conductor (R) is not directly proportional to the current through it, but can show improvements. While this seems to contradict Ohm's Law, it doesn't, because the added output voltage is a product of the input voltage and the voltage recovered by the third trace.

### BRIEF DESCRIPTION OF THE DRAWINGS

FIG. 1 is a schematic of the basic Inductive current circuit showing the primary components.

FIG. 2 is a schematic of the Standard Circuit showing the IC with other standard electrical components.

FIG. 3 is a schematic of the IPA circuit in use with a microcontroller.

FIG. 4 is a schematic of the IPA circuit with two poly capacitors.

### DETAILED DESCRIPTION OF THE INVENTION

Detailed embodiments of the present invention are disclosed herein. It is to be understood that the disclosed embodiments are merely exemplary of the invention, and that there may be a variety of other alternate embodiments. The figures are not necessarily to scale, and some features may be exaggerated or minimized to show details of particular components. Therefore, specified structural and functional details disclosed herein are not to be interpreted as limiting, but merely as a basis for teaching one skilled in the art to employ the varying embodiments of the present invention.

As shown in FIG. 1, which depicts the most basic IPA circuit, the IPA circuit generally has four primary components: a Poly capacitor 20, a dialectic capacitor 30, an inductor 40 and a third trace 50. This basic circuit is attached to a transformer or other power source 10. In the IPA circuit we use the far-right output leg of the transformer. The Poly Capacitor 20 (polymer capacitor), in the preferred embodiment it is not over 0.400 uF. (uF, or microfarads are a measure of capacitance.). The dielectric capacitor 30, will “starve” the inductor 40 of all but its first cycle. The inductor 40, or coil, uses counter-clockwise wraps on a nonferrous core. The “third trace” 50 may be devised in less efficient circuits from the invention's leg wires or otherwise must surround the full board. The output of the inductor 40 goes to third trace 50.

The IPA circuit typically begins off the right-hand side of the inverter/converter transformer 10 where current is directed into the poly capacitor 20 to smooth current fluctuations. This smoothed current then flows into a dialectic capacitor 30 which is used to starve the natural conversion cycles in the inductor 40 to produce inductive power which is amplified throughout IPA's circuit twice, once when the conversion cycle in the inductor 40 is starved at its peak energy potential, and secondly (and most importantly) when dissipating, airborne field flux current (or noise) throughout the electric circuit is captured onto the third trace 50. The inductor 40 must be wound with wire or wrapped and sized to the application circuit. The inductor 40 can be of various shapes-either a coiled, donut shape or straight, choke type inductor depending on the application computations which dictate sizing necessary to starve the cycles. This also means the IPA circuit can be designed to meet specific current and voltage requirements such that it can be scaled to specific application purposes. Sizing electronic components in an IPA circuit is done by using a special IPA benchmark calculation metric (0.734) that is unique to the invention, enabling it to produce optimal results. That effectively means that a one Ohm resistor added to this IPA circuit will effectively be a 0.734 Ohm resistor.

As noted, an inductor is a coil of wire. When current runs through the first loop of the inductor 40, it creates a magnetic field that passes through the other loops. A changing magnetic field will create an electric field in other loops. The direction of this electric field will make a change in electric potential that acts like a battery. In the end, we have a device that has a potential difference that is proportional to the time rate of change of the current (since the (I) current makes the magnetic field.)

The formula for the winding or loop on an inductor is:

ΔV_{L}=−L dl/dt (Eq. 1).

In this equation inductance L depends on the geometry of the inductor coil, and is measured in Henrys. (Henrys are amps/second at 1 volt.) The negative sign on the right side of the equation means the change in potential across the inductor opposes the change in current.

In a typical inductor, if you have a constant current (DC current), then there is no change in the frequency and thus no difference in potential across the inductor—the inductor acts like it's not even there. If there is a high frequency current (AC circuit) then there will be a large difference in potential across the inductor. Inductors reach their potential to produce expected power only after completing 5 cycles. This is a known physical property of inductors. The five cycles must pass through the inductor for a normal response. The Inductive Power Amplification circuit starves all but the first conversion cycles from completing in the inductor by aid of the capacitor that is sized to do so. When the capacitor stores and releases energy at rapid intervals, it constantly creates a difference in the magnetic field which causes an increase in voltage and to a lesser degree amperage, though these are specified by the circuitry design. Voltage rises according to the load but will stabilize in amplitude upon exit from the third trace, producing stable output wattage. In circuits utilizing the component wires as a third trace, the power output will not be at its peak but is sufficient for certain design builds.

IPA technology not only starves the inductor but also makes available extra power that is the result of clearing the electron paths and accelerating or increasing the value of the energy that is produced from the accelerated electron movement. The IPA circuit greatly improves the photovoltaic reaction making solar cells more highly efficient. So instead of a present-day inverter which stabilizes and congests the electron movement, we have an IPA inverter circuit which allows the electrons to move freely through cleared silicon paths. The IPA circuit can be utilized inside the solar cell as well as after the collector in a field array of solar cells to significantly generate multiplicative output power.

Here is the equation for a standard inductor:

L=(μ·k·N²·S)/l (Eq. 2)

### Where: L=Inductance (H)

U=Magnetic permeability (H/m)
K=Nagaoka coefficient
N=Number of turns of the coil
S=Cross-sectional area of the coil (m²)
l=length of coil in axial direction (m)

Eq. 2 is the standard equation for the performance of an inductor. A strong magnetic field is generated by increasing the cross-sectional area of the inductor, or by changing the core of the inductor and the more turns with which the inductor is wound around its core the stronger the magnetic field that can be generated. The current invention's circuit design seeks to optimize that strength. In one preferred embodiment, we have found that wrapping the inductor 17-25 counter-clockwise turns gives the best performance in tandem with a 100 uF dielectric capacitor and 22 awg copper wire. To scale up the output for larger power applications multiple series of the IPA technology with banks of transformers and resistors would be utilized. For example, to produce 3 phase power a Wye Wye connection to the IPA technology would be employed. This is a representative example only, and the technology can work with more, or less, windings, and with differently sized capacitors.

For a capacitor the electric charge on the plates within the capacitor creates an electric field inside the capacitor. Since there is an electric field, there must also be an electric current potential across the plates. The value of this potential depends on the amount of charge. The potential current (Q) across the capacitor can be described by the formula below. But by starving the inductor, IPA accelerates this process thereby accelerating the electron movement.

ΔVc=Q/C (Eq. 3).

Here C is the value of the capacitance in units of Farads. Capacitance is also determined by the physical properties of the IPA circuit. In the case of the IPA circuit, the difference in our configuration from any other present-day circuit is that we connect a poly-capacitor from the output leg of the transformer and the output of the poly-capacitor connects to a dielectric capacitor. The output of the dielectric capacitor 30 which is partially suspended or airborne, connects to the input of the inductor (coil) 40 which is also airborne and then the inductor output is grounded onto the third trace 50 then out to service. So while the capacitor is starving the inductor of its cycles, the inductor in turn is dragging the capacitor, making the capacitor more efficient while producing greater voltage through repeated cycles. Basically in the IPA circuit, you have a solid state generator with the inductor acting as the stator accelerating power that is amplified primarily because of greater voltage.

The inductor potential voltage will be greater than that across the capacitor since the capacitor loses its charge with current flow. The current reverses direction and again charges up the capacitor. This cycle repeats forever with no resistance. Lacking resistance, you have no heat. Suppose we have an ideal physics environment—perfect wires (no resistance) in the circuit on the instant right when connecting a capacitor to an inductor. It would be expressed like this:

ΔV_{c}+ΔV₁=0 Q/C−L·dl/dt=0

Q and I change with time. There is a connection between Q and I because the current it the time rate of change of the charge leaving the capacitor.

I=dq/dt Q/C=−L·d²Q/dt²

A second order differential equation for the charge variable explains the amplification:

Q=LC·d²Q/dt² Q(t)=Q0 cos(wt) w=1/√LC

Understanding inductors 40 in IPA Technology: When a passing current goes through a wire it creates a magnetic field. A magnetic field is induced perpendicular to the wire. As a matter of science, the magnetic field flows throughout the circuit. If it runs out to a capacitor, diode, resister, Zener diodes etc., there is not much change in value of the wattage. But in a transformer it collapses temporarily until the change in wave frequency exits. Then the magnetic field yields approximately the same current but usually amplified voltage. The current may change if the voltage is higher. As seen in the diagram below, a lower current produces a smaller magnetic field.

With IPA technology, the inductive pull in the circuit creates larger rings throughout the circuit and supplies a larger magnetic field to the transformer. In the IPA circuit the transformer actually pulls and drains the circuit whilst the capacitor refires and continues it. As the current is coming out of the transformer the cycles that would ordinarily complete or be converted are starved creating inductive power throughout the circuit. That is, before the 5 cycles take place in the inductor, they are starved by the discharge of the capacitor which disallows the 5 cycles to occur accelerating the magnetic field. The same power transference occurs in a stator on a generator—the conversion cycle is also starved. There is a constant state of energy generation because the spinning magnets in a generator disallow the cycles of the inductor via polarity changes. As a result of the magnets alternating North to South there is a large increase in magnetic flux in the generator stators or inductor causing the induction of accelerated current. In Inductive Power Amplification the same phenomenon occurs—only in a solid-state circuit. The IPA circuit uses the poly capacitor to smooth this acceleration into a stable current; generators by contrast have packings that absorb this rapid change allowing a smooth disbursement of current. This causes an increase of voltage at the poly and throughout the IPA circuit. The IPA circuit harnesses the extra voltage by its unique design and configuration. Amperage stays relatively stable. The increase in voltage yields greater wattage output. (volts'amps=wattage).

Einstein suggested that a wire and magnet creates an inductive current mechanically, whereas Inductive Power Amplification (IPA) produces the same current electronically. Every time a capacitor pauses the flow of the current and the (stator) or inductor is starved at the second cycle, the capacitor discharges and resets the inductor, causing an increase in current flow and starving the circuit throughout. The compression point of the magnetic field occurs at the beginning of the inductor. A greater voltage generally occurs but current now remains relatively unchanged. The voltage can be adjusted up or down with the size of the capacitor. A smaller capacitor would allow all five cycles and voltage would remain unchanged. So the ideal capacitor is one that starves the inductor of all but its first cycle, allowing voltage to increase because of the compressed field width of the magnetic flux.

The inductor 40 stays at peak energy in its first cycle, which is the strongest point of magnetic flux which is a result of the capacitor resetting the cycles causing an acceleration or amplification throughout the whole circuit. So if an IPA circuit is used with a solar cell the Inductive Power Amplification (IPA) technology, causes the electrons to be drained or pulsed so that instead of congesting they are accelerated through a clear path, through the silicon. This causes faster electron movement and enhances the potential power output through the solar cell by heretofore indemonstrable values.

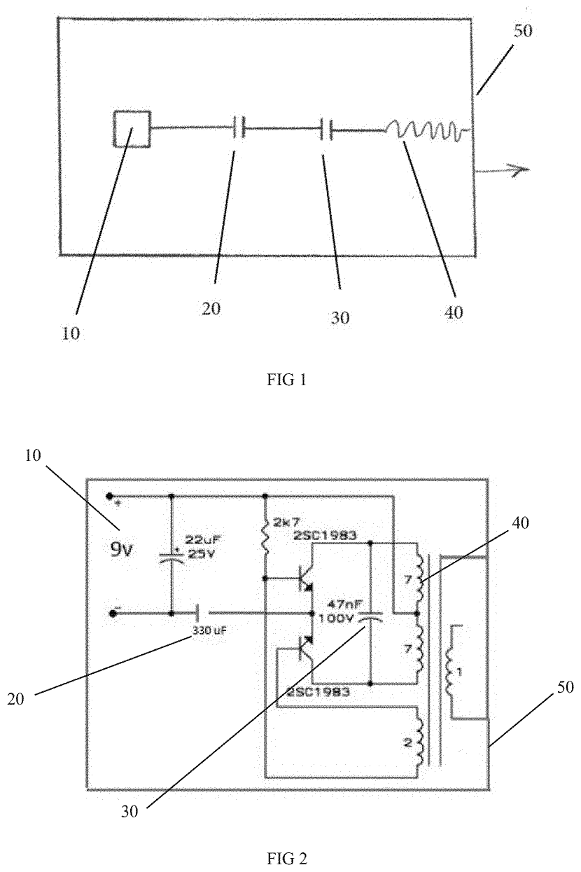

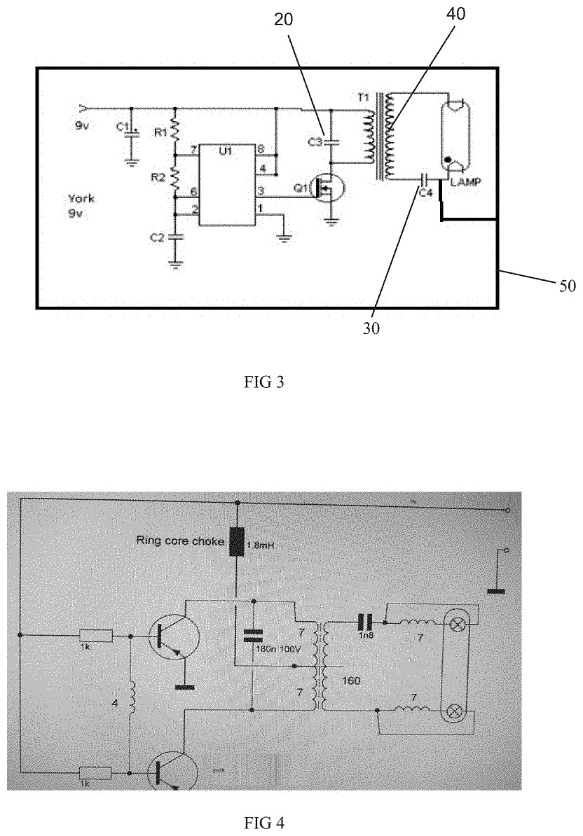

The preceding information relates to the basic IPA circuit and the interplay between the dielectric capacitor 30, the inductor 40, and the third trace 50. But IPA technology can, and does, work within standard electric circuits, and can work with both DC and AC power. FIG. 2, FIG. 3, and FIG. 4 show three typical circuits employing IPA technology. FIG. 2 is the IPA technology in a standard electric circuit using a 9 volt battery as the power source 10. In this system the dielectric capacitor 30 is a 47 nF capacitor, and the Poly capacitor 20 is a 330 g capacitor. This system also uses a number of different resistors and a 22 μf capacitor in parallel with the battery 10.

FIG. 3 shows the IPA technology in use with a microcontroller U1. In this system there are also two other capacitors C1 and C2, along with a transistor Q1 and a transformer T1. FIG. 4 shows the IPA circuit in use with two poly capacitors. The IPA circuit can be used in many different configurations, and with many different electric circuits, both AC and DC. It should be noted that the configuration of parts in the IPA circuit do not always have to be linear nor do parts need to be board pinned. Improvement can occur by the poly(s), dielectric capacitor and inductor being air born as long as the inductor is the last part to terminate into the third trace. Such a configuration is not a recommended use and mentioned solely to document the fact that air born parts connected can yield similar efficiency improvement as an alternative to extra spacing or stand-off of IPA parts from others in an electrical circuit. Moreover, to boost amperage without a corresponding increase in voltage two polys, one of greater size, can be substituted for the dielectric capacitor with adjustment to the wraps on the inductor.

The present invention is well adapted to carry out the objectives and attain both the ends and the advantages mentioned, as well as other benefits inherent therein. While the present invention has been depicted, described, and is defined by reference to particular embodiments of the invention, such reference does not imply a limitation to the invention, and no such limitation is to be inferred. The depicted and described embodiments of the invention are exemplary only, and are not exhaustive of the scope of the invention. Consequently, the present invention is intended to be limited only by the spirit and scope of the claims, giving full cognizance to equivalents in all respects.

We claim:

1. An apparatus for inductive current amplification comprising:
an electric circuit consisting of a power source;
a poly capacitor electrically attached to said power source;
a dielectric capacitor electrically attached to said poly capacitor;
an inductor electrically attached to said dielectric capacitor, said inductor consisting of a wire in multiple winds;
a conductive pathway attached as the last wind of said inductor:
wherein said electric circuit creates an electromagnetic flux; and
wherein said conductive pathway is wound around said electric circuit to capture said electromagnetic flux to amplify the current from the inductor.

2. The apparatus of claim 1 wherein said inductor naturally completes five cycles and wherein further said dielectric capacitor interacts with said inductor to prevent it from completing all but the first circuit, thereby increasing the electromagnetic flux of said inductor.
